(19) United States
(12) Patent Application Publication
(10) Pub. No.: US 2019/0165202 A1
(43) Pub. Date: May 30, 2019

(54) Film Drawing Device and Method

(71) Applicant: Beijing Chuangyu Technology Co., Ltd, Beijing (CN)

(72) Inventors: Jincheng ZOU, Beijing (CN); Min WEI, Beijing (CN); Bingbing SHEN, Beijing (CN)

(21) Appl. No.: 16/022,718

(22) Filed: Jun. 29, 2018

(30) Foreign Application Priority Data
Nov. 29, 2017 (CN) 201711230737.2

(51) Int. Cl. H01L 31/18; H01L 31/0236; B23Q 3/08; B29C 55/20

(52) U.S. Cl. CPC H01L 31/18; H01L 31/0236; B23Q 2701/01; B29C 55/20; B23Q 2240/002; B23Q 3/088

(57) ABSTRACT

The present disclosure relates to the technical field of solar cells, and more particularly to a film drawing device and method. The film drawing device includes a fixing component and a moving component. The fixing component includes a first fixing plate and a second fixing plate. The first fixing plate and the second fixing plate are opposite to each other and are configured to fix two ends of a film respectively. The moving component is connected to the first fixing, plate and/or the second fixing plate to drive the first fixing plate and/or the second fixing plate to move so as to draw the film. The film drawing device can draw the film. Finally, the entire surface of the film is smooth without folds, precise positioning is facilitated, and the problem of folds formed after bonding is solved.

### TECHNICAL FIELD

The present disclosure relates to the technical field of solar cells, and more particularly to a film drawing device and method.

### BACKGROUND

In a manufacturing process, it is necessary to bond a film to a frame having certain hardness for transportation and subsequence processing. Since the film is soft, the film needs to be drawn to make the entire surface smooth, and then can be precisely positioned and bonded to the frame. At present, in the field, the film is not drawn before being bonded to the frame, the bonded film has folds, and there is a problem that the film cannot be accurately positioned before being drawn.

### SUMMARY

### (1) Technical Problem to be Solved

The technical problem to be solved by some embodiments of the present disclosure is a problem in the related art that folds are formed after a film is bonded to a frame.

### (2) Technical Solution

In order to solve the above technical problem, an embodiment provides a film drawing device, which includes a fixing component and a moving component. The fixing component includes a first fixing plate and a second fixing plate. The first fixing plate and the second fixing plate are opposite to each other and are configured to fix two ends of a film respectively. The moving component is connected to the first fixing plate and/or the second fixing plate to drive the first fixing plate and/or the second fixing plate to move so as to draw the film.

In an exemplary embodiment, the fixing component further includes a first pressing plate and a second pressing plate, and the first pressing plate and the second pressing plate are disposed in correspondence to the first fixing plate and the second fixing plate respectively, so as to press the two ends of the film on the upper surfaces of the first fixing plate and the second fixing plate respectively.

In an exemplary embodiment, the fixing component further includes a driving element, and the driving element is connected to the first pressing plate and the second pressing plate to control the first pressing plate and the second pressing plate to press the two ends of the film on upper surfaces of the first fixing plate and the second fixing plate respectively.

In an exemplary embodiment, the driving element includes a first rotating shaft driver and a second rotating shaft driver, the first rotating shaft driver is connected to a rotating shaft of the first pressing plate to control the first pressing plate to rotate toward the first fixing plate, and the second rotating shaft driver is connected to a rotating shaft of the second pressing plate to control the second pressing plate to rotate toward the second fixing plate.

In an exemplary embodiment, the first fixing plate and the second fixing plate are provided with vacuum suction holes separately.

In an exemplary embodiment, a vacuum generation device is further included. The vacuum generation device fixes the film to the first fixing plate and the second fixing plate through the vacuum suction holes.

In an exemplary embodiment, the moving component includes a pushing element and a guide rail, the guide rail is disposed along the drawing direction of the film, the first fixing plate and/or the second fixing plate are/is disposed on the guide rail, and the pushing element is connected to the first fixing plate and/or the second fixing plate to push the first fixing plate and the second fixing plate to move oppositely along the guide rail.

In an exemplary embodiment, the pushing element includes a servo motor and a screw nut component, an output shaft of the servo motor is connected to the screw nut component through a coupling, and the screw nut component is connected to the first fixing plate and/or the second fixing plate through a pushing block.

In an exemplary embodiment, a fixing plate is further included. The servo motor is fixed to the fixing plate through a motor fixing seat, the screw nut component is fixed to the fixing plate through a screw supporting seat, and the guide rail is fixed to the fixing plate.

In an exemplary embodiment, a control element is further included. The control element includes a sensor and a controller, the sensor is configured to detect the drawing degree of the film and transmit a detection signal to the controller, and the controller is connected to the moving component so as to control a movement distance of the first fixing plate and/or the second fixing plate under the drive of the moving component through the detection signal.

The present disclosure also provides a film drawing method, which includes the following steps:

S1. Two ends of a film are respectively fixed to a first fixing plate and a second fixing plate, which are opposite to each other.

S2. A moving component is started to drive the first fixing plate and the second fixing plate to move oppositely, or to drive the second fixing plate to move away from the first fixing plate.

Herein, step S1 specifically includes the following steps:

S11. The film is conveyed to the first fixing plate and the second fixing plate through a manipulator.

S12. A first pressing plate and a second pressing plate, which are disposed correspondingly to the first fixing plate and the second fixing plate and opposite to each other, are started to press the two ends of the film on the upper surfaces of the first fixing plate and the second fixing plate.

Herein, after step S12, the method further includes the following step:

S13. The first fixing plate and the second fixing plate respectively suck the two ends of the film.

Herein, step S1 specifically includes the following steps:

S11. The film is conveyed to the first fixing plate and the second fixing plate through a manipulator.

S12. The first fixing plate and the second fixing plate respectively suck the two ends of the film.

### (3) Beneficial Effect

The above technical solution of the present disclosure has the following advantages. According to the film drawing device and method, after two ends of the film are fixed by the first fixing plate and the second fixing plate of the fixing component, the first fixing plate and the second fixing plate are driven by the moving component to simultaneously or separately move, so that the first fixing plate and the second fixing plate move away from each other to draw the film. Finally, the entire surface of the film is smooth without folds, precise positioning is facilitated, and the problem of folds formed after bonding is solved.

Besides the above-described technical problem to be solved by the present disclosure, the technical features of the technical solution and the advantages brought by these technical features of the technical solution, other technical features of the present disclosure and advantages brought by these technical features will be further illustrated with reference to the accompanying drawings.

### BRIEF DESCRIPTION OF THE DRAWINGS

FIG. 1 is a schematic structure diagram of a film drawing device according to an embodiment of the present disclosure;

FIG. 2 is a schematic structure diagram of a film drawing device according to an embodiment of the present disclosure before a film is drawn; and

FIG. 3 is a schematic structure diagram of a film drawing device according to an embodiment of the present disclosure after a film is drawn.

In the drawings, 1, fixing component; 2, moving component; 3, vacuum suction hole; 4, fixing plate; 5, film; 11, first fixing plate; 12, second fixing plate; 13, first pressing plate; 14, second pressing plate; 15, driving element; 21, pushing element; 22, guide rail; 41, motor fixing seat; 42, screw supporting seat; 151, first rotating shaft driver; 152, second rotating shaft driver; 211, serve motor; 212, screw nut component; 213, coupling; 214, pushing block.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described hereinbelow with the drawings in the embodiments of the present disclosure. Obviously, the described embodiments are only part of the embodiments of the present disclosure, not all of the embodiments. On the basis of the embodiments of the present disclosure, all other embodiments obtained on the premise of no creative work of a person of ordinary skill in the art fall within the scope of protection of the present disclosure.

In the descriptions of the present disclosure, unless otherwise specified and limited, it should be noted that terms “mounting”, “mutual connection” and “connection” should be generally understood. For example, the term may be fixed connection, or detachable connection or integrated connection, may be mechanical connection or electrical connection, may be direct connection, may be indirect connection through an intermediate, or may be internal communication between two elements. A person of ordinary skill in the art may understand specific meanings of the above terms in the present disclosure according to specific situations.

In addition, in the descriptions of the present disclosure, unless otherwise specified and limited, “multiple”, “multiple pieces” and “multiple groups” mean two or more, and “several”, “several pieces” and “several groups” mean one or more.

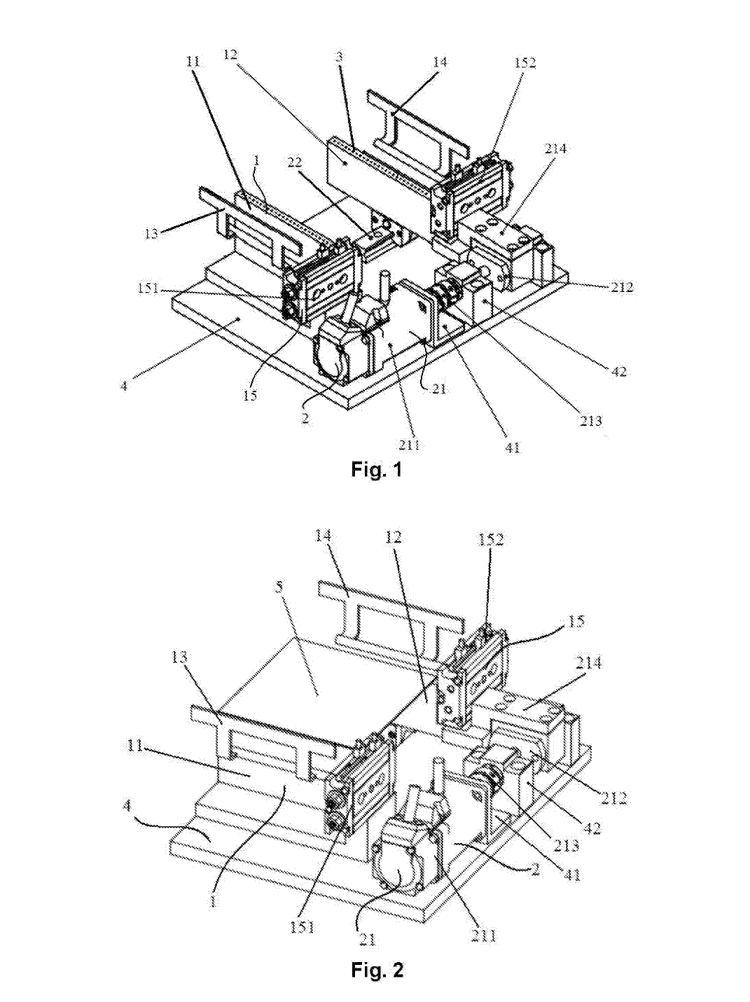

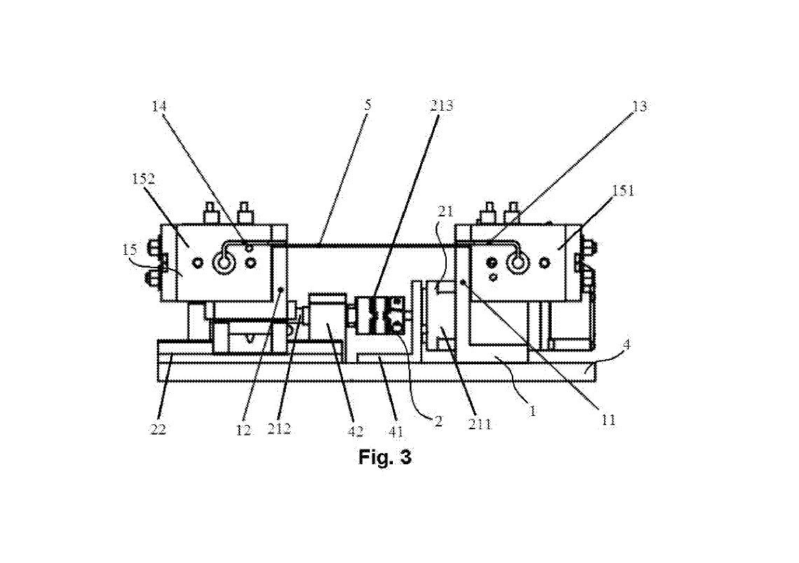

As shown in FIG. 1, FIG. 2 and FIG. 3, a film drawing device provided according to an embodiment of the present disclosure includes a fixing component 1 and a moving component 2. The fixing component 1 includes a first fixing plate 11 and a second fixing plate 12. The first fixing plate 11 and the second fixing plate 12 are opposite to each other and are configured to fix two ends of a film 5 respectively. The moving component 2 is connected to the first fixing plate 11 and/or the second fixing plate 12 to drive the first fixing plate 11 and/or the second fixing plate 12 to move so as to draw the film 5.

According to the film drawing device of the present disclosure, after the two ends of the film 5 are fixed by the first fixing plate 11 and the second fixing plate 12 of the fixing component, the first fixing plate 11 and the second fixing plate 12 are driven by the moving component 2 to simultaneously or separately move, so that the first fixing plate 11 and the second fixing plate 12 move away from each other to draw the film 5. Finally, the entire surface of the film 5 is smooth without folds, precise positioning is facilitated, and the problem of folds formed after bonding is solved.

The two ends of the film 5 can be fixed to the first fixing plate 11 and the second fixing plate 12 in a manner such as bonding, pressing and sucking. In the present embodiment, the joint manner of pressing and sucking is adopted. Therefore, the fixing component 1 further includes a first pressing plate 13 and a second pressing plate 14, and the first pressing plate 13 and the second pressing plate 14 are disposed in correspondence to the first fixing plate 11 and the second fixing plate 12 respectively, so as to press the two ends of the film 5 on the upper surfaces of the first fixing plate 11 and the second fixing plate 12 respectively. After the first pressing plate 13 and the second pressing plate 14 press the film 5 on the first fixing plate 11 and the second fixing plate 12 in advance, the first fixing plate 11 and the second fixing plate 12 perform sucking and fixing, so that the success rate of sucking can be ensured, and the fixing degree of the film is effectively improved. Herein, the fixing component 1 further includes a driving element 15, and the driving element 15 is connected to the first pressing plate 13 and the second pressing plate 14 to control the first pressing plate 13 and the second pressing plate 14 to press the two ends of the film 5 on the upper surfaces of the first fixing plate 11 and the second fixing plate 12 respectively. The driving element 15 may adopt a device similar to a telescopic cylinder to linearly drive and control the first pressing plate 13 and the second pressing plate 14 to lift and fall so as to press the film 5, and may also adopt a device similar to a swinging cylinder and a motor to rotationally drive and control the first pressing plate 13 and the second pressing plate 14 to turn and cover so as to press the film 5. Moreover, the first pressing plate 13 and the second pressing plate 14 may be provided with a drive separately, or may be provided with a drive jointly.

Specifically, the present embodiment includes a turn-to-cover driving element 15, the turn-to-cover driving element 15 drives two pressing plates separately. The driving element 15 includes a first rotating shaft driver 151 and a second rotating shaft driver 152, the first rotating shaft driver 151 is connected to a rotating shaft of the first pressing plate 13 to control the first pressing plate 13 to rotate toward the first fixing plate 11, and the second rotating shaft driver 152 is connected to a rotating shaft of the second pressing plate 14 to control the second pressing plate 14 to rotate toward the second fixing plate 12. The first rotating shaft driver 151 can control the first pressing plate 13 to rotate toward the first fixing plate 11 back and forth for 90°, and the second rotating shaft driver 152 can control the second pressing plate 14 to rotate toward the second fixing plate 12 back and forth for 90°, so that the pressing plates can press the film 5 before drawing, and can leave the film 5 after drawing. In the present embodiment, the first rotating shaft driver 151 is connected to the first fixing plate 11 through a bolt, and the second rotating shaft driver 152 is connected to the second fixing plate 12 through a bolt.

Herein, the first fixing plate 11 and the second fixing plate 12 are provided with vacuum suction holes 3 separately. The top surfaces of the first fixing plate 11 and the second fixing plate 12 are provided with a certain number of vacuum suction holes 3, which are used for providing a vacuum suction force in a vertical direction to suck the film 5, and vacuum suction can ensure a certain suction force while exerting a small destructive force on the film 5, so the film 5 cannot be damaged in a suction drawing process. After the first pressing plate 13 and the second pressing plate 14 press the film 5, the first fixing plate 11 and the second fixing plate 12 suck and fix the film, thereby facilitating a suction fixing effect.

The film drawing device of the present embodiment further includes a vacuum generation device. The vacuum generation device fixes the film 5 to the first fixing plate 11 and the second fixing plate 12 through the vacuum suction holes 3. The vacuum suction forces generated by the first fixing plate 11 and the second fixing plate 12 are implemented by a vacuum generator. In other embodiments of the present embodiment, for convenience of operation, a pressing plate may not be adopted, but a suction hole or a strip-shaped suction groove is provided on the fixing plate to fix the film.

Further, the moving component 2 includes a pushing element 21 and a guide rail 22, the guide rail 22 is disposed along the drawing direction of the film 5, the second fixing plate 12 is disposed on the guide rail 22, and the pushing element 21 is connected to the second fixing plate 12 to push the second fixing plate 12 to move away from the first fixing plate 11 along the guide rail 22. The bottom of the second fixing plate 12 is connected to a sliding block through a bolt, and the sliding block is disposed on the guide rail 22 and linearly slides along the guide rail 22. The pushing element 21 may adopt a driving element similar to a cylinder or a screw nut to achieve linearly back and forth movement. In other embodiments of the present disclosure, guide rails may also be mounted under the first fixing plate and the second fixing plate. The pushing element may separately or simultaneously control the first fixing plate and the second fixing plate to push the first fixing plate and the second fixing plate to move away from each other.

Further, the pushing element 21 includes a servo motor 211 and a screw nut component 212, an output shaft of the servo motor 211 is connected to the screw nut component 212 through a coupling 213, and the screw nut component 212 is connected to the second fixing plate 12 through a pushing block 214. In the present embodiment, a motor driven screw is selected as the pushing element 21, and the movement distance of the driven element can be easily and accurately controlled. When the server motor 211 moves, a screw of the screw nut component 212 can be driven to rotate, and the screw rotates to drive a nut of the screw nut component 212 to linearly move on the screw. When the nut moves, the pushing block 214 connected to the nut is driven to move, so as to drive the second fixing plate 12 to linearly move on the guide rail 22 back and forth, thereby drawing the film 5.

The film drawing device of the present embodiment further includes a fixing plate 4. The first fixing plate 11 is fixed to the fixing plate 4. The servo motor 211 is fixed to the fixing plate 4 through a motor fixing seat 41, the screw nut component 212 is fixed to the fixing plate 4 through a screw supporting seat 42, and the guide rail 22 is fixed to the fixing plate 4. The guide rail 22 is fixed to the fixing plate through a bolt. One end of the motor fixing seat 41 is connected to the servo motor 211 through a bolt, and the other end is fixed to the fixing plate 4. The screw nut component 212 is fixed to the fixing plate 4 through the screw supporting seat 42, the screw supporting seat 42 includes a supporting-side screw supporting seat and a fixing-side screw supporting seat, the supporting-side screw supporting seat and the fixing-side screw supporting seat are fixed to the fixing plate 4 through bolts, and fixing through a bolt structure facilitates disassembling.

The film drawing device of the present embodiment further includes a control element. The control element includes a sensor and a controller, the sensor is configured to detect the drawing degree of the film 5 and transmit a detection signal to the controller, and the controller is connected to the moving component 2 so as to control a movement distance of the first fixing plate 11 and/or the second fixing plate 12 under the drive of the moving component through the detection signal 2. The controller acquires drawing information of the film 5, detected by the sensor, so as to control the start/stop action of the pushing element 21, thereby ensuring the consistency of the drawing degree of the film 5, and preventing the film 5 from being broken and damaged due to over-drawing.

The present embodiment also provides a film drawing method, which includes the following steps:

S1. Two ends of a film 5 are respectively fixed to a first fixing plate 11 and a second fixing plate 12, which are opposite to each other.

S2. A moving component 2 is started to drive the first fixing plate 11 and the second fixing plate 12 to move oppositely, or to drive the second fixing plate 12 to move away from the first fixing plate 11.

Herein, step 51 specifically includes the following steps:

S11. The film 5 is conveyed to the first fixing plate 11 and the second fixing plate 12 through a manipulator.

S12. A first pressing plate 13 and a second pressing plate 14, which are disposed correspondingly to the first fixing plate 11 and the second fixing plate 12 and opposite to each other, are started to press the two ends of the film 5 on the upper surfaces of the first fixing plate 11 and the second fixing plate 12.

According to the film drawing method of the present embodiment, after the two ends of the film 5 are pressed on the first fixing plate 11 and the second fixing plate 12 respectively by the first pressing plate 13 and the second pressing plate 14, the first fixing plate 11 and the second fixing plate 12 are driven by the moving component 2 to jointly or separately move, so that the second fixing plate 12 and the first fixing plate 11 move away from each other to draw the film 5. Finally, the entire surface of the film 5 is smooth without folds, precise positioning is facilitated, and the problem of folds formed after bonding is solved.

After step S12, the method further includes the following step:

S13. The first fixing plate 11 and the second fixing plate 12 suck the two ends of the film 5.

According to the film drawing method of the present embodiment, a manner of fixing the film 5 to the first fixing plate 11 and the second fixing plate 12 is not limited to pressing and fixing. In the present embodiment, the first fixing plate 11 and the second fixing plate 12 also have a suction function. After being pressed by the first pressing plate 13 and the second pressing plate 14, the first fixing plate 11 and the second fixing plate 12 further suck and fix the film 5. It should be understood that in an exemplary embodiment may also fix the film only by using a suction manner.

To sum up, according to the film drawing device and method of the some embodiments of the present disclosure, after two ends of the film are sucked and fixed by the first fixing plate and the second fixing plate of the fixing component, the first fixing plate and the second fixing plate are driven by the moving component to simultaneously or separately move, so that the second fixing plate and the first fixing plate move away from each other to draw the film. Finally, the entire surface of the film is smooth without folds, precise positioning is facilitated, and the problem of folds formed after bonding is solved.

It shall be, finally, noted that: the above embodiments are merely intended to illustrate the technical solutions of the present disclosure and do not limit the technical solutions; although the present disclosure is illustrated in detail with reference to the above embodiments, a person of ordinary skill in the art shall understand that they can still modify the technical solutions recorded by the above embodiments or can equivalently replace some of the technical features; and these modifications or replacements do not make the essences of corresponding technical solutions depart from the spirit and scope of the technical solutions in each embodiment of the present disclosure.

What is claimed is:

1. A film drawing device, wherein the film drawing device comprises a fixing component and a moving component, the fixing component comprises a first fixing plate and a second fixing plate; the first fixing plate and the second fixing plate are opposite to each other and are configured to fix two ends of a film respectively; and the moving component is connected to the first fixing plate and/or the second fixing plate to drive the first fixing plate and/or the second fixing plate to move so as to draw the film.

2. The film drawing device as claimed in claim 1, wherein the fixing component further comprises a first pressing plate and a second pressing plate, and the first pressing plate and the second pressing plate are disposed in correspondence to the first fixing plate and the second fixing plate respectively, so as to press the two ends of the film on upper surfaces of the first fixing plate and the second fixing plate respectively.

3. The film drawing device as claimed in claim 2, wherein the fixing component further comprises a driving element, and the driving element is connected to the first pressing plate and the second pressing plate to control the first pressing plate and the second pressing plate to press the two ends of the film on the upper surfaces of the first fixing plate and the second fixing plate respectively.

4. The film drawing device as claimed in claim 3, wherein the driving element comprises a first rotating shaft driver and a second rotating shaft driver, the first rotating shaft driver is connected to a rotating shaft of the first pressing plate to control the first pressing plate to rotate toward the first fixing plate, and the second rotating shaft driver is connected to a rotating shaft of the second pressing plate to control the second pressing plate to rotate toward the second fixing plate.

5. The film drawing device as claimed in claim 1, wherein the first fixing plate and the second fixing plate are provided with vacuum suction holes separately.

6. The film drawing device as claimed in claim 5, wherein the film drawing device further comprises a vacuum generation device, the vacuum generation device fixes the film to the first fixing plate and the second fixing plate through the vacuum suction holes.

7. The film drawing device as claimed in claim 1, wherein the moving component comprises a pushing element and a guide rail, the guide rail is disposed along the drawing direction of the film, the first fixing plate and/or the second fixing plate are/is disposed on the guide rail, and the pushing element is connected to the first fixing plate and/or the second fixing plate to push the first fixing plate and the second fixing plate to move oppositely along the guide rail.

8. The film drawing device as claimed in claim 7, wherein the pushing element comprises a servo motor and a screw nut component, an output shaft of the servo motor is connected to the screw nut component through a coupling, and the screw nut component is connected to the first fixing plate and/or the second fixing plate through a pushing block.

9. The film drawing device as claimed in claim 8, wherein the film drawing device further comprises a fixing plate, wherein the servo motor is fixed to the fixing plate through a motor fixing seat, the screw nut component is fixed to the fixing plate through a screw supporting seat, and the guide rail is fixed to the fixing, plate.

10. The film drawing device as claimed in claim 9, further comprising a control element, wherein the control element comprises a sensor and, a controller, the sensor is configured to detect the drawing degree of the film and transmit a detection signal to the controller, and the controller is connected to the moving component so as to control a movement distance of the first fixing plate and/or the second fixing plate under the drive of the moving component through the detection signal.

11. The film drawing device as claimed in claim 2, wherein the first fixing plate and the second fixing plate are provided with vacuum suction holes separately.

12. The film drawing device as claimed in claim 3, wherein the first fixing plate and the second fixing plate are provided with vacuum suction holes separately.

13. The film drawing device as claimed in claim 4, wherein the first fixing plate and the second fixing plate are provided with vacuum suction holes separately.

14. A film drawing method. wherein the film drawing method comprises the following steps:
S1: respectively fixing two ends of a film to a first fixing plate and a second fixing plate, which are opposite to each other; and
S2: starting a moving component to drive the first fixing plate and the second fixing plate to move oppositely, or to drive the second fixing plate to move away from the first fixing plate.

15. The film drawing method as claimed in claim 14, wherein step S1 specifically comprises the following steps:
S11: conveying the film to the first fixing plate and the second fixing plate through a manipulator; and
S12: starting a first pressing plate and a second pressing plate, which are disposed correspondingly to the first fixing plate and the second fixing plate and opposite to each other, to press the two ends of the film on the upper surfaces of the first fixing plate and the second fixing plate.

16. The film drawing method as claimed in claim 15, wherein after step S12, the method further comprises the following step:
S13: the first fixing plate and the second fixing plate respectively suck two ends of the film.

17. The film drawing method as claimed in claim 14, wherein step S1 specifically comprises the following, steps:
S11: conveying the film to the first fixing plate and the second fixing plate through a manipulator; and
S12: the first fixing plate and the second fixing plate respectively suck two ends of the film.
